(19) United States
(12) Patent Application Publication
(10) Pub. No.: US 2011/0169136 A1
(43) Pub. Date: Jul. 14, 2011

(54) CROSSBAR-INTEGRATED MEMRISTOR ARRAY AND METHOD EMPLOYING INTERSTITIAL LOW DIELECTRIC CONSTANT INSULATOR

(76) Inventors: Matthew D. Pickett, San Francisco, CA (US); Dmitri B. Strukov, Mountain View, CA (US)

(21) Appl. No.: 12/687,798

(22) Filed: Jan. 14, 2010

(51) Int. Cl. H01L 29/86; H01L 21/02

(52) U.S. Cl. 257/537; 438/385; 257/E21.006; 257/E29.325

(57) ABSTRACT

A memristor crossbar array and method of making employ an interstitial insulator. The memristor crossbar array includes a plurality of memristors in an array. The memristors include columns of memristor material disposed between and connecting to a first plurality of wire electrodes and a second plurality of wire electrodes at cross points between the respective wire electrodes. The memristor crossbar array further includes an insulator of a solid material in an interstitial space between the wire electrodes of the first plurality and between the columns of memristor material. The insulator isolates the memristors from one another and has a dielectric constant that is lower than a dielectric constant of the memristor material. The method of making includes forming the plurality of memristors and filling the interstitial space between adjacent memristors with the insulator material.

### CROSS-REFERENCE TO RELATED APPLICATIONS

N/A

### STATEMENT REGARDING FEDERALLY SPONSORED RESEARCH OR DEVELOPMENT

N/A

### BACKGROUND

A memristor is a two-terminal electrical device that may function as a passive current limiter in which an instantaneous resistance state is a function of bias history. Specifically, an electrical flux or a time integral of the electric field, between terminals of the memristor is a function of the amount of electric charge, or a time integral of a current, that has passed through the memristor. As such, a memristor represents a two-terminal device that effectively has a memory of its ‘state’ (e.g. resistance) that is a function of its bias history. Moreover, the bias history is solely dependent on the amount of electric charge that has passed through the device. In other words, memristor resistance may be changed by applying a programming signal to the memristor (e.g., by applying a voltage across the two terminals and passing a current through the memristor), for example.

Notably, memristors may be switched between ‘states’ (e.g., using the programming signal) and therefore are potentially useful as programmable circuit elements for a variety of memory circuits and related applications. Moreover, the programmed state of the memristor is maintained without power such that memristors may function as inherently non-volatile memory elements. For example, a memristor may be switched by a programming signal between an ‘ON’ state and an ‘OFF’ state effectively implementing a binary memory cell or element. In another application, the memristor may be switched or programmed to assume any one of several intermediate states between the ON state and the OFF state using the programming signal. Moreover, the memristor may be used to record and retain an analog level facilitating its use in circuits such as neural networks.

In practical implementations, memristors are often employed in a crossbar array. Conventional memristor crossbar arrays typically comprise a first layer of wire electrodes and a second layer of wire electrodes separated from one another by a continuous film or layer of memristor material. Unfortunately, conventional materials employed to realize a memristor exhibit relatively high dielectric constants. The high dielectric constant of memristor materials results in a relatively high parasitic capacitance between the wire electrodes of the memristor crossbar array. In addition, the continuous memristor material layer may not provide particularly good electrical isolation between individual memristors within the memristor crossbar array. One or both of the poor electrical isolation and the relatively high parasitic capacitance may limit the switching speed as well as an ultimate minimum size of elements that make up the memristor crossbar array.

### BRIEF DESCRIPTION OF THE DRAWINGS

The various features of embodiments of the present invention may be more readily understood with reference to the following detailed description taken in conjunction with the accompanying drawings, where like reference numerals designate like structural elements, and in which:

FIG. 1 illustrates a cross sectional view of an exemplary memristor, according to an embodiment of the present invention.

FIG. 2 illustrates a schematic diagram of an exemplary memristor-based memory circuit, according to an embodiment of the present invention.

FIG. 3 illustrates cross sectional view of a memristor crossbar array, according to an embodiment of the present invention.

FIG. 4 illustrates a perspective view of the memristor crossbar array illustrated in FIG. 3, according to an embodiment of the present invention.

FIG. 5 illustrates a flow chart of a method of making a memristor crossbar array, according to an embodiment of the present invention.

FIGS. 6A-6D illustrate exemplary stages in the method of making a memristor crossbar array illustrated in FIG. 5 that employs hole filling to form the plurality of memristors, according to an embodiment of the present invention.

FIG. 7 illustrates a flow chart of a method of making a memristor crossbar array, according to another embodiment of the present invention.

FIGS. 8A-8D illustrate exemplary stages in the method of making a memristor cross bar array illustrated in FIG. 7, according to an embodiment of the present invention.

Certain embodiments of the present invention have other features that are one of in addition to and in lieu of the features illustrated in the above-referenced figures. These and other features of the invention are detailed below with reference to the preceding drawings.

### DETAILED DESCRIPTION

Embodiments of the present invention provide a memristor crossbar array with electrically isolated memristors. In particular, according to embodiments of the present invention adjacent memristors in the crossbar array are electrically isolated from one another by an insulator material. Further, the insulator material has a dielectric constant that is lower than a dielectric constant of a material of the memristors. The lower dielectric constant may reduce, and in some embodiments may minimize, a parasitic capacitance between wire electrodes of the memristor crossbar array when compared to conventional memristor crossbar arrays that employ a continuous layer of memristor material. Reducing parasitic capacitance may concomitantly reduce cross talk between wire electrodes of the memristor crossbar array. The reduced parasitic capacitance and concomitant reduced crosstalk may facilitate one or both of smaller dimensions (i.e., denser memristor arrays) and higher switching speeds of the memristors within memristor crossbar arrays, according to some embodiments of the present invention.

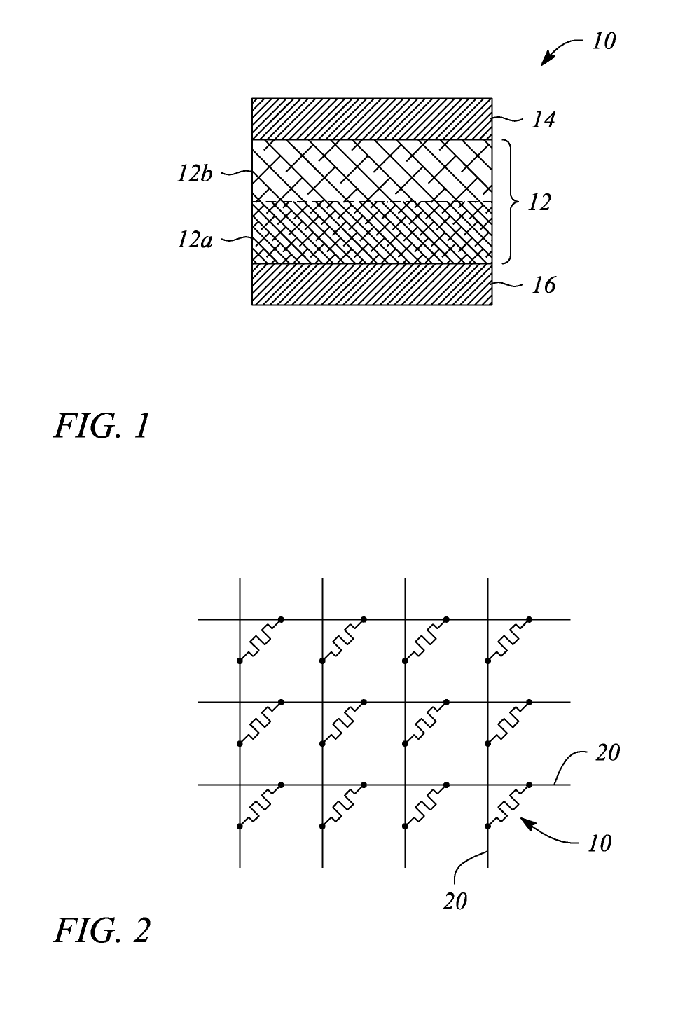

FIG. 1 illustrates a cross sectional view of an exemplary memristor 10, according to an embodiment of the present invention. The memristor 10 is a two terminal device comprising a layer 12 of memristor material. A memristor material is a material that exhibits a memristor phenomenon or characteristic when subjected to a voltage. The memristor 10 is disposed between a first or ‘top’ electrode 14 and a second or ‘bottom’ electrode 16. The first and second electrodes 14, 16 facilitate applying the programming signal (e.g., a voltage) to affect a change in the memristor material layer 12. The change in the memristor material layer 12 produced by the programming signal may be understood in terms of oxygen migration within the memristor material layer 12, according to some embodiments. For example, a boundary between a layer of memristor material 12b that is deficient in oxygen and another effectively ‘normal’ memristor material layer 12a (i.e., oxide that is not oxygen deficient) may move as a result of exposure to the programming signal. The movement of the boundary may result from oxygen migration under the influence of the programming signal, for example. A final location of the movable boundary may establish the ‘programmed’ resistance of the memristor 10, for example.

In some embodiments, the memristor material layer 12 is a thin film layer having a thickness on the order of several tens of nanometers. For example, the memristor material layer 12 may have a thickness between about 10 nanometers (nm) to about 100 nm. In another example, the thin film memristor material layer 12 may be between about 20 nanometers (nm) and about 50 nm thick.

In various embodiments, the memristor material layer 12 of the memristor 10 may be effectively any oxide that can be formed into a layer between a pair of electrodes. For example, titanium oxide (TiO₂) may be used as the oxide layer in a memristor. Other oxides that may be employed include, but are not limited to, nickel oxide, nickel oxide doped with chromium, strontium titanium oxide, strontium titanium oxide doped with chromium, and tungsten oxide.

In some embodiments, the oxide layer 12 may comprise a crystalline oxide. In some of these embodiments, the crystalline oxide may be mono-crystalline. In other embodiments, the oxide layer 12 comprises an amorphous oxide. In yet other embodiments, the oxide layer comprises either a nanocrystalline oxide or a microcrystalline oxide. A nanocrystalline oxide is an oxide that includes or comprises a plurality of nano-scale crystallites while a microcrystalline oxide may include crystallites having sizes in the micron range, for example. In some embodiments, the oxide layer may comprise a plurality of layers. A first layer of the plurality may be a normal oxide (e.g., TiO₂) while a second layer may be an oxygen depleted or oxygen deficient oxide layer (e.g., TiO₂₋ₓ where ‘2−x’ denotes an oxygen deficit, where x is greater than 0 and less than about 2). For example, the oxygen deficient TiO₂₋ₓ may have values of x that are greater than about 10⁻⁵ and less than about 10⁻². In another example, the oxygen deficient TiO₂₋ₓ may have a value of x that ranges up to about 1.

An oxygen deficient oxide layer may be produced by exposing a surface of the oxide layer (e.g., TiO₂) to a gas mixture of 95% nitrogen (N₂) and 5% hydrogen (H₂) at a temperature of about 550 degrees C. for about 2 hours, for example. The gas mixture effectively removes oxygen from the oxide layer leaving the oxygen deficient oxide layer in a portion of the oxide layer near the surface. The oxygen deficient layer may have ‘oxygen vacancies’ that may act as n-type dopants within the oxide layer. The presence of these oxygen vacancies may allow the oxide layer to function as an electron donor doped semiconductor, for example.

The first and second electrodes 14, 16 comprise a conductor. For example, the first electrode and the second electrode may comprise a conductive metal. The conductive metal used for the first and second electrodes may include, but is not limited to, gold (Au), silver (Ag), copper (Cu), aluminum (Al), palladium (Pd), platinum (Pt), tungsten (W) and titanium (Ti) as well as alloys thereof, for example. Other conductive metals and other conductive materials (e.g., a highly doped semiconductor) may also be employed as the first electrode and the second electrode, according to various embodiments. Moreover, the conductive material need not be the same in the first and second electrodes. Additionally, the first and second electrodes may comprise more than one layer. For example, a layer of Ti may be employed between a Pt-based electrode and a TiO₂ oxide layer. The Ti layer may assist in providing an oxygen deficient layer (i.e., TiO₂₋ₓ) in the oxide layer, for example.

Embodiments of the present invention are applicable to a wide variety of memristor-based circuits. For example, an array of memristors 10 may be provided as a memory circuit. FIG. 2 illustrates a schematic diagram of an exemplary memristor-based memory circuit, according to an embodiment of the present invention. For example, the exemplary memristor-based memory circuit illustrated in FIG. 2 may be implemented as a ‘crossbar’ array. As illustrated, rows of memristors 10 are connected together with a common conductor referred to as a ‘bit line’ 20. Another bit line 20 connects columns of memristors 10. Parallel bit lines 20 may be implemented as parallel conductor traces or ‘wire electrodes’, for example.

By definition herein, a ‘cross point’ is a point at which two wires cross over or under one another. For example, a cross point of wire electrodes in a cross bar array is a point where a wire electrode of a first layer crosses under a wire electrode of another (e.g., overlying) layer. A cross point between wire electrodes is generally created by two wire electrodes that have different orientations. For example, a pair of wire electrodes that are oriented substantially perpendicular or orthogonal to one another may cross over one another at some point along their respective lengths. The point at which the wire electrodes cross is the ‘cross point’. Importantly however, while a cross point necessary involves wires crossing one another, the wires may not actually contact one another at the cross point. For example, a crossbar array comprises a plurality of wire electrode cross points. However, the wire electrodes in a first layer are generally spaced apart from wire electrodes in a second layer of the crossbar array by the memristive layer or memristor in between the two wires (e.g., spaced by a memristor at the cross points).

Further herein, the term ‘solid’ when applied to a material is defined as a state of matter in which a ‘solid’ material has structural rigidity and does not readily flow, deform or change shape. As such, the term solid is meant to explicitly distinguish over a liquid or a gas state of matter (i.e., a solid is not a fluid or a gas). In general, a solid material may comprise a crystalline material, a polycrystalline material or an amorphous material. Note that some super cooled liquids (e.g., glass) are considered a solid under this definition. Likewise, a rigid foam may be a solid regardless of the presence of holes between material that makes up the rigid foam.

Further, as used herein, the article ‘a’ is intended to have its ordinary meaning in the patent arts, namely ‘one or more’. For example, ‘a memristor’ means one or more memristors and as such, ‘the memristor’ explicitly means ‘the memristor(s)’ herein. Also, any reference herein to ‘top’, ‘bottom’, ‘upper’, ‘lower’, ‘up’, ‘down’, ‘front’, back', ‘left’ or ‘right’ is not intended to be a limitation herein. Herein, the term ‘about’ when applied to a value generally means plus or minus 10% unless otherwise expressly specified. Moreover, examples herein are intended to be illustrative only and are presented for discussion purposes and not by way of limitation.

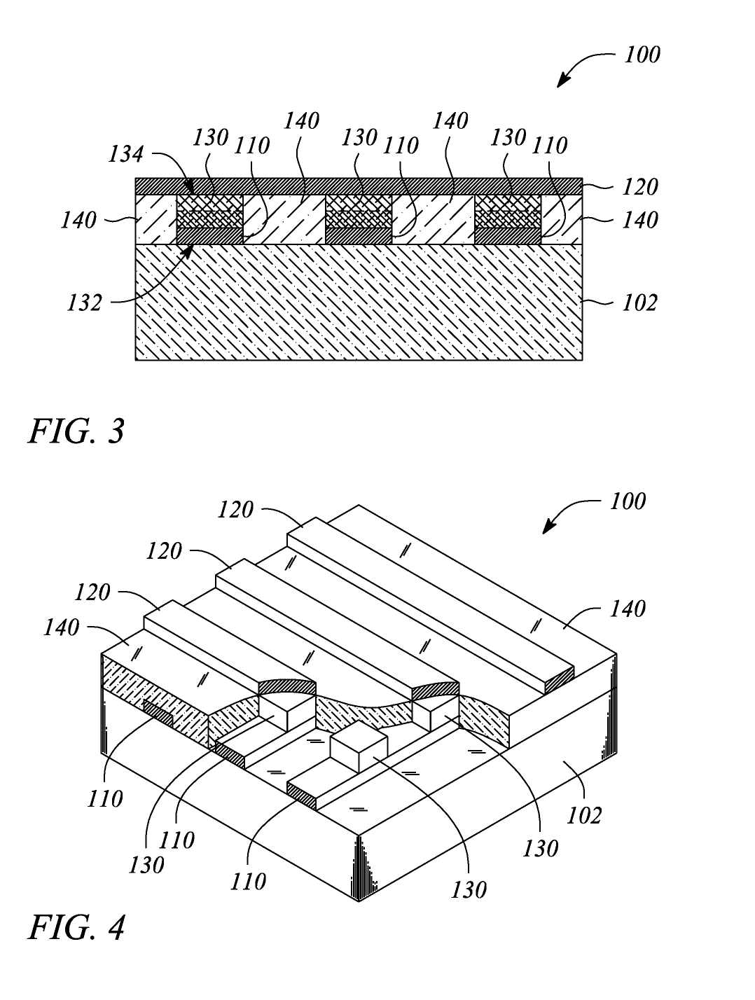

FIG. 3 illustrates cross sectional view of a memristor crossbar array 100, according to an embodiment of the present invention. FIG. 4 illustrates a perspective view of the memristor crossbar array 100 illustrated in FIG. 3, according to an embodiment of the present invention. A portion of the memristor crossbar array 100 illustrated in FIG. 4 is cut away to expose details of underlying structure and elements, for clarity of discussion only. Also, for discussion purposes, the memristor crossbar array 100 is illustrated on a substrate 102 in FIGS. 3 and 4.

As illustrated in FIGS. 3 and 4, the memristor crossbar array 100 comprises a first plurality of wire electrodes 110 in a first layer and a second plurality of wire electrodes 120 in a second layer. The first layer may be adjacent to (e.g., formed on top of or within) a surface of the substrate 102, for example. The first layer is spaced apart from the second layer. For example, the second layer is above (i.e., vertically spaced apart from) the first layer, as illustrated in FIGS. 3 and 4. The wire electrodes 110, 120 comprise a conductive material. In some embodiments, the wire electrodes 110, 120 comprise a conductive metal. For example, the wire electrodes 110, 120 may comprise one of platinum (Pt), gold (Au), silver (Ag) or copper (Cu).

Wire electrodes 110, 120 in each of the first plurality and the second plurality are generally non-intersecting. In some embodiments, the wire electrodes 110, 120 within respective ones of the first layer and the second layer are substantially parallel to one another. Wire electrodes 110 of the first plurality in the first layer are oriented in a direction that differs from an orientation of wire electrodes 120 of the second plurality in the second layer such that a plurality of cross points are formed between individual wire electrodes 110, 120. In some embodiments, the wire electrodes 110 are oriented substantially orthogonal (i.e., approximately 90 degrees) to the wire electrodes 120.

The memristor crossbar array 100 illustrated in FIGS. 3 and 4 further comprises a plurality of memristors 130. The memristors 130 are disposed between and connect to the wire electrodes 110 in the first layer and the wire electrodes 120 in the second layer at the cross points. In particular, an individual memristor 130 connects to a particular wire electrode 110 of the first plurality at a first or bottom terminal 132 of the individual memristor 130. Similarly, a second or top terminal 134 of the individual memristor 130 connects to a particular wire electrode 120 of the second plurality. The connections of the terminal 132, 134 occurs at or in a vicinity of the cross point of the particular wire electrodes 110, 120. The memristors 130 comprise a memristor material. For example, the memristor may comprise titanium dioxide (TiO₂). In such an exemplary memristor 130, a variable layer or portion of the TiO₂ may be oxygen deficient (e.g., may comprise TiO₂₋ₓ).

The memristor cross bar array 100 further comprises an insulator 140. The insulator 140 comprises a solid material having a dielectric constant that is lower than a dielectric constant of the memristor material. Further, since a solid material is employed, the dielectric constant of the insulator 140 is greater than that of air (i.e., 1.0) by definition. For example, the insulator 140 may comprise silicon dioxide (SiO₂) when the memristor 130 comprises TiO₂. The dielectric constant of SiO₂ used for an exemplary insulator 140 may be between about 2.0 and about 3.9 while the exemplary TiO₂ of the memristor 130 may have a dielectric constant of between about 80 and about 170 (e.g., ˜100). The insulator 140 is located in an interstitial space between the wire electrodes 110, 120 and the memristors 130. The insulator 140 electrically isolates adjacent memristors 130 from one another.

In particular, in some embodiments the insulator 140 substantially fills an interstitial space below a wire electrode 120 of the second plurality of wire electrodes 120 and between adjacent memristors 130 arranged in a row along the wire electrode 120, as illustrated in FIG. 3. Adjacent memristors 130 in the row are electrically isolated from one another by the insulator 140. In some embodiments, for example as illustrated in FIG. 4, the insulator 140 may also substantially fill an interstitial space between adjacent rows of memristors 130 associated with adjacent wire electrodes 120 of the second plurality. As such, the insulator 140 may substantially fill all of the space between adjacent memristors 130 both within rows and between rows. In such embodiments, the insulator 140 may also fill the interstitial space between wire electrodes 110. Alternatively (not illustrated), the insulator 140 may electrically isolate adjacent memristors 130 within a row while another means (e.g., air or a vacuum) provides electrical isolation between adjacent rows. In some embodiments, the insulator 140 may support the wire electrodes 120 between memristors 130.

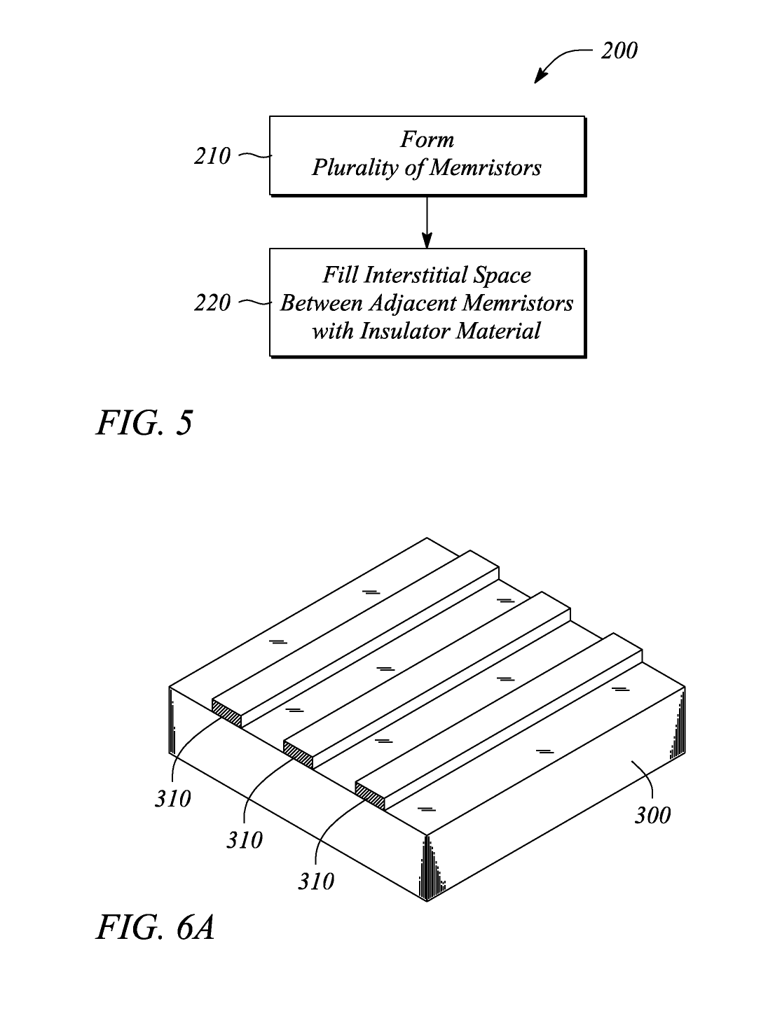

FIG. 5 illustrates a flow chart of a method 200 of making a memristor crossbar array, according to an embodiment of the present invention. The method of making a memristor crossbar array comprises forming 210 a plurality of memristors. The formed 210 plurality of memristors connect between a first plurality of wire electrodes and a second plurality of wire electrodes at cross points between wire electrodes of the first plurality and wire electrodes of the second plurality. The method 200 of making a memristor crossbar array further comprises filling 220 an interstitial space between adjacent memristors with an insulator material. The insulator material used to fill 220 the interstitial space is substantially solid and has a dielectric constant that is lower than a dielectric constant of a material of the memristors. The insulator material provides electrical isolation between adjacent memristors of the memristor crossbar array.

In some embodiments (not illustrated), forming 210 the plurality of memristors and filling an interstitial space comprises forming the first plurality of wire electrodes. For example, a layer of metal may be deposited on a substrate and then patterned to form the wire electrodes of the first plurality. Forming 210 further comprises depositing a layer of memristor material over the first plurality of wire electrodes. The memristor material layer may be deposited using chemical vapor deposition (CVD), sputtering, atomic layer deposition (ALD) or another deposition method, for example. Forming 210 further comprises patterning the memristor material to isolate columns of memristor material on the wire electrodes of the first plurality. The isolated columns are located at points on the wire electrodes of the first plurality corresponding to locations of the cross points. Forming 210 further comprises forming the second plurality of wire electrodes on top of the isolated columns.

In some embodiments, forming the second plurality of wire electrodes is performed after filling 220 the interstitial space between adjacent memristors. For example, the insulator material may be deposited around the columns of memristor material (e.g., using CVD). After the insulator material is deposited, chemical-mechanical polishing, or another technique, may be employed to expose the tops of the isolated columns of memristor material. The second plurality of wire electrodes may then be formed on top of the insulator material and isolated columns embedded in the insulator material in a manner analogous to forming the first plurality of wire electrodes.

In other embodiments, forming 210 the plurality of memristors comprises forming holes in the insulator material at the cross points. Forming 210 the plurality of memristors further comprises filling the holes with memristor material to provide the memristors. Once the holes are filled and the memristors formed 210, remaining insulator material fills 220 the interstitial space between adjacent memristors.

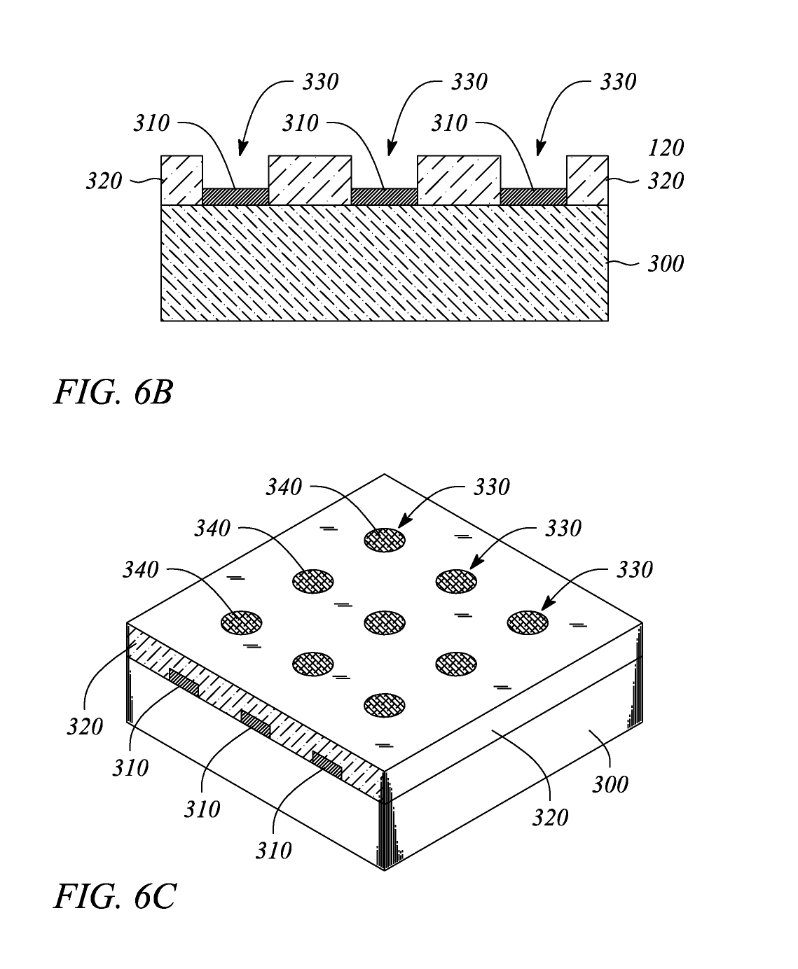

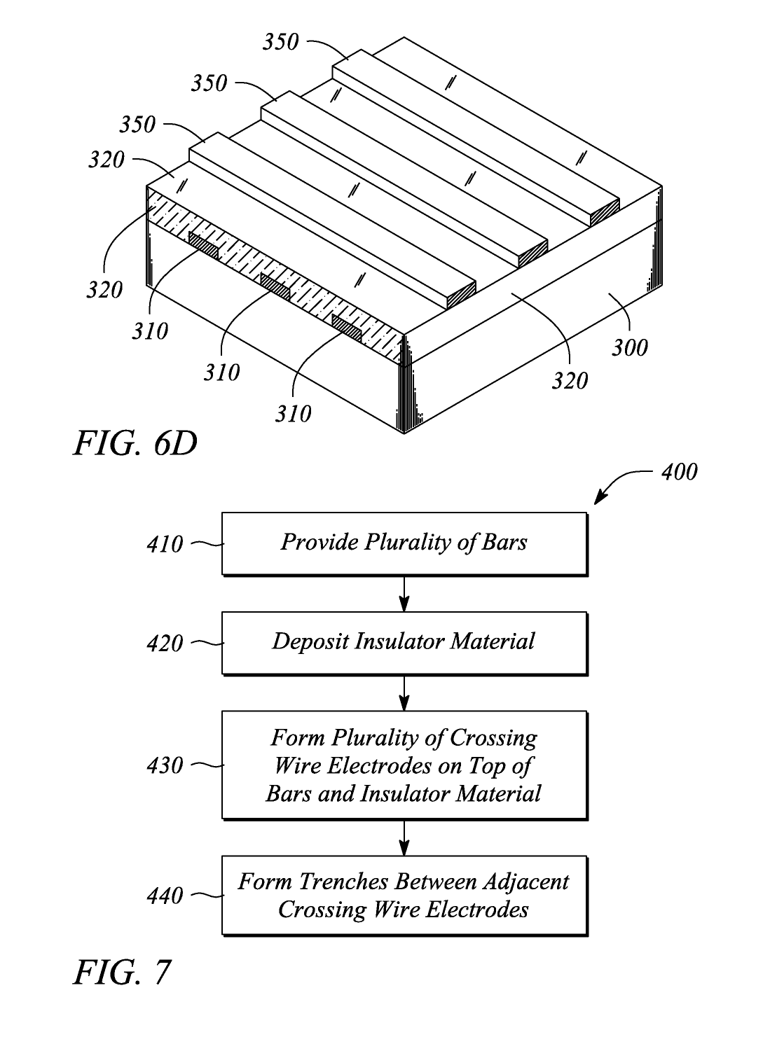

FIGS. 6A-6D illustrate exemplary stages in the method 200 of making a memristor crossbar array employing hole filling to form 210 the plurality of memristors, according to an embodiment of the present invention. In particular, FIG. 6A illustrates a perspective view of a substrate 300 with the first plurality of wire electrodes 310 formed on a surface. For example, the wire electrodes 310 may be formed by depositing a layer of metal on the substrate and then patterning the deposited metal layer. A metal layer may be deposited using a technique including, but not limited to, electrodeposition, sputtering, evaporation and CVD. The metal layer may be patterned into the first plurality of wire electrodes 310 using etching or a dual damascene process, for example.

FIG. 6B illustrates a cross sectional view of the substrate 300 with an insulator 320 deposited over the formed first plurality of wire electrodes 310. For example, CVD may be employed to deposit a thin film or layer of silicon dioxide to create the insulator 320. Also illustrated in FIG. 6B are holes 330 formed in the insulator 320. The holes 330 extend from a surface of the insulator 320 to a top surface of the wire electrodes 310, as is illustrated in FIG. 6B.

In some embodiments, the holes 330 are formed by selectively removing portions of the insulator 320 at points along the wire electrodes 310 corresponding to eventual locations of the cross points of the memristor crossbar array. For example, a mask may be applied to the insulator 320 and reactive ion etching (RIE) may be used to form (e.g., drill) the holes 330. In other embodiments (not illustrated), the insulator 320 may be deposited in a manner that produces the holes during deposition (e.g., around sacrificial posts on the wire electrodes).

FIG. 6C illustrates a perspective view of the substrate 300 with the insulator 320 after the holes have been filled with memristor material 340. For example, the holes may be filled using CVD to deposit the memristor material 340 into the holes 330. The memristor material 340 may be deposited through a mask aligned with the holes 330, for example. Removal of the mask removes memristor material 340 that deposits outside of the holes through a lift-off process, for example. In some embodiments, the mask used for filling and lift-off may be the same mask used to define the holes 330, obviating potential alignment issues.

In another example, the memristor material is deposited without a mask. Memristor material (not illustrated) that deposits on top of the insulator 320 outside of the holes 330 may be removed by chemical mechanical polishing or using another procedure, for example. FIG. 6D illustrates a perspective view of a completed memristor crossbar array on the substrate 300. In particular, FIG. 6D illustrates the substrate 300 and the insulator 320 after the second plurality of wire electrodes 350 have been formed on the top surface of the insulator 320. The second plurality of wire electrodes 350 covers the holes 330 and the memristor material 340 in the holes 330 and therefore are not illustrated in FIG. 6D. The second plurality of wire electrodes 350 may be formed in a manner analogous to forming the first plurality of wire electrodes 310, for example. As illustrated in FIG. 6D, the insulator 320 fills 220 substantially all of the interstitial space between adjacent memristors of the completed memristor crossbar array.

FIG. 7 illustrates a flow chart of a method 400 of making a memristor crossbar array, according to another embodiment of the present invention. The method 400 of making a memristor crossbar array comprises providing 410 a plurality of bars. The provided 410 bars are spaced apart from one another and comprise a wire electrode with a layer of a memristor material on a top surface of the wire electrode. As such, the term ‘bar’ as employed with respect to the method 400 of making a memristor crossbar array is explicitly defined herein to be a composite structure comprising the wire electrode and memristor material layer. In some embodiments, providing 410 a plurality of bars may comprise depositing the layer of memristor material (e.g., TiO₂) on a previously deposited layer of conductor material (e.g., metal). The deposited layers of memristor material and conductor material may then be patterned (e.g., by lithography and etching) to define the plurality of spaced apart bars, for example. In another example, the conductor material and memristor material may be successively deposited through a mask that defines the plurality of spaced apart bars.

The method 400 of making a memristor crossbar array further comprises depositing 420 an insulator material that substantially fills a space between adjacent bars of the plurality. The deposited 420 insulator material has a dielectric constant that is less than the dielectric constant of the memristor material, in some embodiments. For example, an insulator material (e.g., SiO₂) may be deposited using CVD. Deposition may be performed through a mask that preferentially directs the insulator material into the spaces between the bars, for example. In another example, the insulator material may be deposited as a conformal layer over the bars and into the spaces between bars. In this example, a method such as chemical-mechanical polishing may be employed to remove insulator material that deposits on top of the bars to expose the memristor material.

The method 400 of making a memristor crossbar array further comprises forming 430 a plurality of crossing wire electrodes on top of the bars and insulator material. The crossing wire electrodes electrically contact the memristor material at cross points. With respect to method 400 of making a memristor crossbar array, the term ‘crossing’ when used in conjunction with wire electrodes is defined to mean that the wire electrodes have an orientation that is different from that of the bars such that the wire electrodes cross the bars (e.g., at an angle) and form cross points where the crossing wire electrodes overlap with the wire electrodes of the bars. In some embodiments, the crossing wire electrodes are oriented substantially perpendicular (i.e., are orthogonal to) the bars.

The method 400 of making a memristor crossbar array further comprises forming 440 trenches between adjacent crossing wire electrodes. The trenches are formed in the memristor material of the bars and the insulator material between the bars. Forming 440 trenches may comprise etching, for example. In some embodiments, a depth of the trench is substantially similar to a thickness of the memristor material of the bars. In such embodiments, the trench may extend to the top surface of the wire electrode of the bars electrically isolating memristors within the bars. Note that the method 400 of making a memristor crossbar array advantageously provides self-alignment of the memristors at cross points of the wire electrodes.

In some embodiments (not illustrated), the method 400 of making a memristor crossbar array may further comprise depositing an insulator material to substantially fill the trenches. The insulator material deposited in the trenches may have a dielectric constant that is lower than the memristor material dielectric constant, in some embodiments. For example, the insulator material (e.g., SiO₂) may be deposit using CVD. In some embodiments, the insulator material that is deposited in the trenches may also be deposited over the crossing wire electrodes.

In some embodiments, providing 410 a plurality of bars and forming 430 plurality of crossing wire electrodes followed by forming 440 trenches of method 400 may be substantially similar to forming 210 a plurality of memristor described with respect to method 200. Similarly, depositing 420 an insulator material that substantially fills a space between adjacent bars and optionally depositing an insulator material to substantially fill the trenches of method 400 may be substantially similar to filling 220 an interstitial space between adjacent memristors with an insulator material described with respect to method 200. That is, the method 200 of making a memristor crossbar array is considered to explicitly include the method 400 of making a memristor crossbar array, according to some embodiments of the present invention.

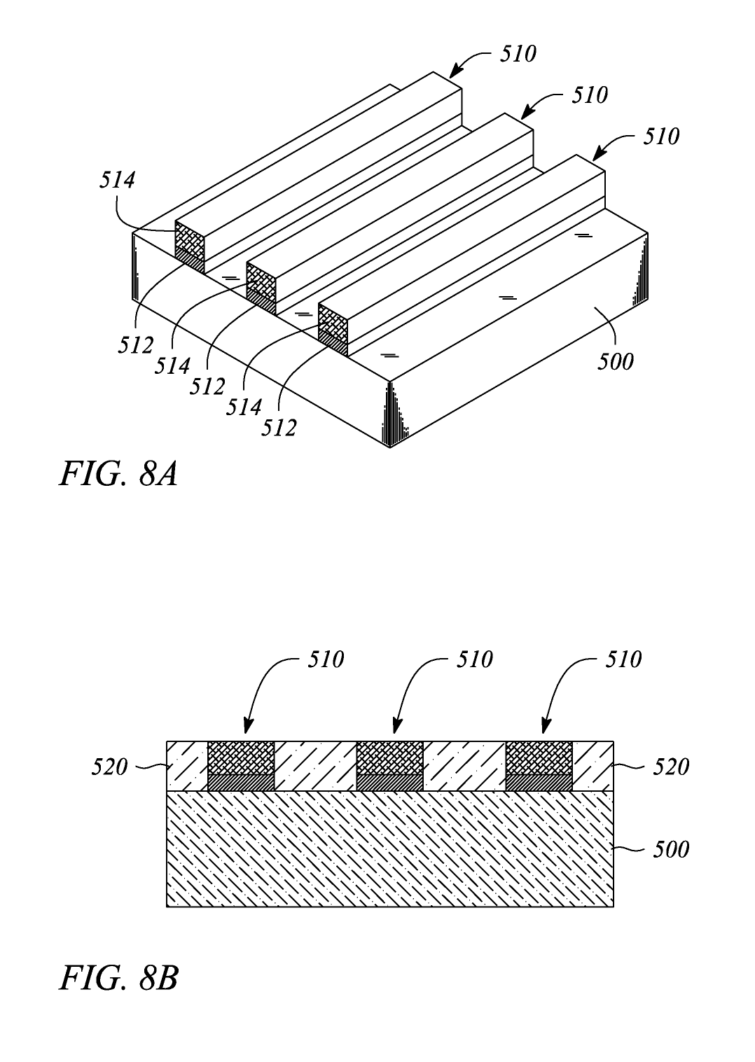

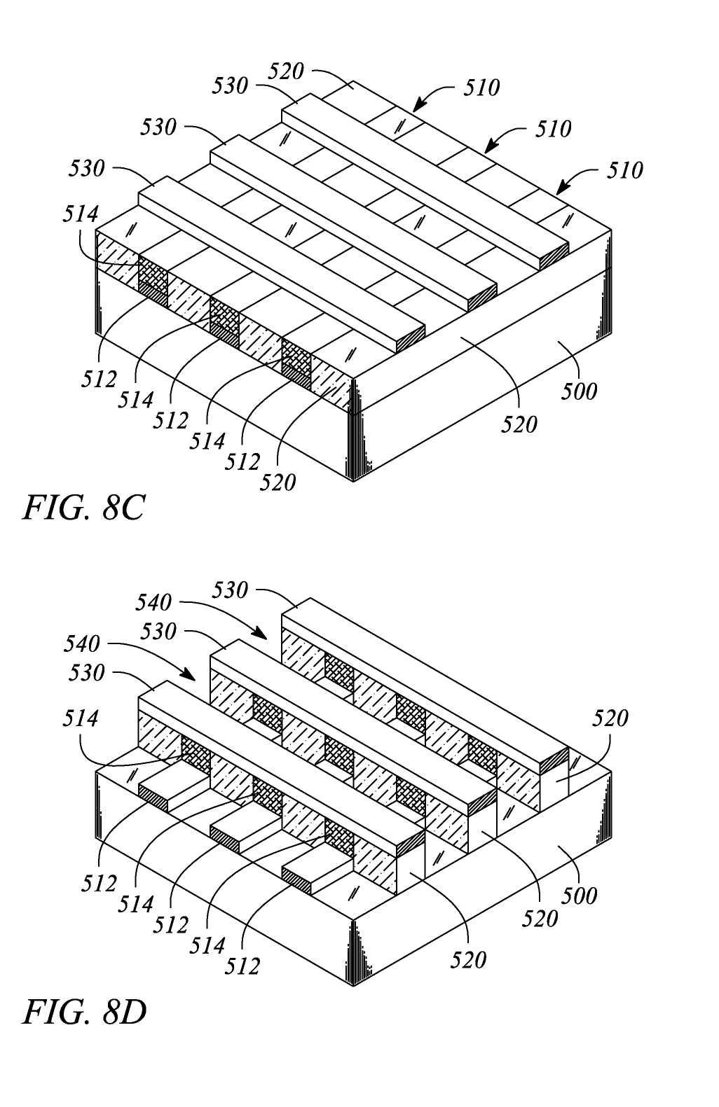

FIGS. 8A-8E illustrate exemplary stages in the method 400 of making a memristor cross bar array, according to an embodiment of the present invention. In particular, FIG. 8A illustrates a perspective view of a substrate 500 with bars 510 that have been formed 410 on a surface of the substrate 500. The bars 510 comprise a wire electrode 512 underlying a layer of memristor material 514. FIG. 8B illustrates a cross sectional view of the substrate 500 and bars 510 after an insulator material 520 has been deposited in spaces between adjacent bars 510. FIG. 8C illustrates a perspective view of the substrate 500 following the formation 430 of a plurality of crossing wire electrodes 530 on top of the bars and the insulator material. As illustrated, the crossing wire electrodes 530 are oriented orthogonal to the bars 510. FIG. 8D illustrates a perspective view of the substrate 500 after trenches 540 have been formed 440 between the crossing wire electrodes 530. In particular, the trenches 540 have a depth that is substantially similar to or greater than a thickness of the memristor material 514. As illustrated in FIG. 8D, the trenches 540 extend to and expose the surface of the substrate 500 in between adjacent wire electrodes 512. The trenches electrically isolate adjacent memristors at cross points along the bars while the deposited 420 insulator material 520 electrically isolates adjacent memristor at cross points along the crossing wire electrodes.

Thus, there have been described embodiments of a memristor crossbar array and methods of making a memristor crossbar array that employ an interstitial low dielectric constant insulator. It should be understood that the above-described embodiments are merely illustrative of some of the many specific embodiments that represent the principles of the present invention. Clearly, those skilled in the art can readily devise numerous other arrangements without departing from the scope of the present invention as defined by the following claims.

What is claimed is:

1. A memristor crossbar array comprising:
a plurality of memristors in an array, the memristors comprising columns of memristor material disposed between and connecting to each of a first plurality of wire electrodes in a first layer and a second plurality of wire electrodes in a second layer at cross points between the respective wire electrodes; and
an insulator in an interstitial space between the wire electrodes and the columns of memristor material, the insulator comprising a solid material having a dielectric constant that is lower than a dielectric constant of a material of the memristors,
wherein the insulator electrically isolates the memristors from one another.

2. The memristor crossbar array of claim 1, wherein the memristor material is titanium dioxide and the insulator comprises silicon dioxide.

3. The memristor crossbar array of claim 1, wherein the wire electrodes comprise gold (Au), silver (Ag), copper (Cu) aluminum (Al), or platinum (Pt).

4. The memristor crossbar array of claim 1, wherein the solid material of the insulator substantially fills an interstitial space below the wire electrodes of the second plurality between and adjacent to the columns of memristor material.

5. The memristor crossbar array of claim 4, wherein the solid material further substantially fills an interstitial space between adjacent rows of the memristors, the rows being defined by adjacent wire electrodes of the second plurality.

6. The memristor crossbar array of claim 1, further comprising a substrate, the first plurality of wire electrodes being adjacent to a surface of the substrate.

7. A method of making a memristor crossbar array comprising:
forming a plurality of memristors in an array, the memristors comprising columns of a memristor material that connects between a wire electrode of a first plurality of wire electrodes and a wire electrode of a second plurality of wire electrodes at cross points between respective wire electrodes of the first plurality and the second plurality;
filling an interstitial space between adjacent memristors with an insulator material that is a solid, the insulator material having a dielectric constant that is lower than a dielectric constant of a material of the memristors,
wherein the insulator material provides electrical isolation between adjacent memristors.

8. The method of making a memristor crossbar array of claim 7, wherein forming the plurality of memristors comprises:
forming the first plurality of wire electrodes;
depositing a layer of memristor material over the first plurality of wire electrodes;
patterning the memristor material to isolate the columns of memristor material on the wire electrodes of the first plurality; and
forming the second plurality of wire electrodes across tops of the isolated columns.

9. The method of making a memristor crossbar array of claim 7, wherein forming the plurality of memristors and filling an interstitial space comprise:
forming the first plurality of wire electrodes;
forming a layer of a solid insulator material on the first plurality of wire electrodes;
forming holes in the insulator material that delineate the cross points; and
filling the holes with the memristor material to provide the columns of memristors.

10. The method of making a memristor crossbar array of claim 9, wherein filling the holes with the memristor material is performed prior to forming the second plurality of wire electrodes.

11. The method of making a memristor crossbar array of claim 7, wherein the insulator material comprises silicon dioxide.

12. The method of making a memristor crossbar array of claim 7, wherein the wire electrodes of the first plurality of wire electrodes and the second plurality of wire electrodes independently comprise one of copper (Cu) or platinum (Pt), and wherein the memristor material comprises titanium dioxide.

13. A method of making a memristor crossbar array comprising:
providing a plurality of bars, the bars being spaced apart from one another and comprising a wire electrode with a layer of memristor material on top a surface of the wire electrode;
depositing an insulator material that substantially fills a space between adjacent bars of the plurality, the insulator material having a lower dielectric constant than a dielectric constant of the memristor material;
forming a plurality of crossing wire electrodes on top of both the bars and the insulator material, the crossing wire electrodes electrically contacting the memristor material at cross points; and
forming trenches between adjacent crossing wire electrodes, the trenches being formed in both the memristor material of the bars and the insulator material between the bars.

14. The method of making a memristor crossbar array of claim 13, further comprising depositing an insulator material to substantially fill the trenches, the insulator material deposited in the trenches having a dielectric constant that is lower than the memristor material dielectric constant.

15. The method of making a memristor crossbar array of claim 13, wherein the memristor material comprises titanium dioxide, the wire electrodes comprising one of copper (Cu) or platinum (Pt), the insulator material comprising silicon dioxide.
